(19) United States
(12) Patent Application Publication
(10) Pub. No.: US 2024/0260408 A1
(43) Pub. Date: Aug. 1, 2024

(54) Transparent Display Device with Touch Sensor

(71) Applicant: LG Display Co., Ltd., Seoul (KR)

(72) Inventors: Dojin Kim, Paju-si (KR); JaeHee Park, Paju-si (KR); MiReum Lee, Paju-si (KR)

(21) Appl. No.: 18/538,774

(22) Filed: Dec. 13, 2023

(30) Foreign Application Priority Data
Jan. 30, 2023 (KR) 10-2023-0011910

(51) Int. Cl. H10K 59/80; H10K 59/40

(52) U.S. Cl. CPC H10K 59/873; H10K 59/40; H10K 59/80521; H10K 59/8792

(57) ABSTRACT

A transparent display device with a touch sensor is provided, which comprises a first substrate provided with a display area including a transmissive area and a non-transmissive area and a non-display area disposed near the display area, a second substrate facing the first substrate, a plurality of subpixels provided in the non-transmissive area on the first substrate, including a light emitting element consisting of an anode electrode, a light emitting layer and a cathode electrode, a touch sensor disposed in the transmissive area on the first substrate, including a touch sensor electrode, and an organic layer provided on one surface of the second substrate, which faces the first substrate, including a first protrusion pattern protruded toward the touch sensor in an area overlapped with the touch sensor.

### CROSS-REFERENCE TO RELATED APPLICATION

This application claims the benefit of the Republic of Korea Patent Application No. 10-2023-0011910 filed on Jan. 30, 2023, which is hereby incorporated by reference in its entirety.

### BACKGROUND

### Field of Technology

The present disclosure relates to a transparent display device with a touch sensor.

### Description of the Related Art

Recently, studies for a transparent display device, in which a user may view objects or images positioned at an opposite side by transmitting the display device, are actively ongoing. The transparent display device includes a transmissive area, in which a display area for displaying an image may transmit external light, and a non-transmissive area. The transparent display device may have high light transmittance in the display area through the transmissive area.

The transparent display device may be provided with a plurality of touch sensors and a plurality of touch lines to implement a touch function. However, the transparent display device has problems in that it is not easy to form the plurality of touch sensors and the plurality of touch lines or a process is complicated and light transmittance may be reduced due to the plurality of touch sensors and the plurality of touch lines.

### SUMMARY

The present disclosure has been made in view of the above problems and it is an object of the present disclosure to provide a transparent display device that may minimize or reduce loss of light transmittance due to a touch sensor and a touch line.

It is another object of the present disclosure to provide a transparent display device that may make sure of high touch performance.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a transparent display device with a touch sensor, the transparent display device comprising a first substrate provided with a display area including a transmissive area and a non-transmissive area and a non-display area disposed near the display area, a second substrate facing the first substrate, a plurality of subpixels provided in the non-transmissive area on the first substrate, including a light emitting element consisting of an anode electrode, a light emitting layer and a cathode electrode, a touch sensor disposed in the transmissive area on the first substrate, including a touch sensor electrode, and an organic layer provided on one surface of the second substrate, which faces the first substrate, including a first protrusion pattern protruded toward the touch sensor in an area overlapped with the touch sensor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a transparent display panel according to one embodiment;

FIG. 2 is a schematic view illustrating an example of a pixel provided in an area A of FIG. 1 according to one embodiment;

FIG. 3 is a view illustrating an example of signal lines, touch lines, and a touch sensor, which are provided in an area ‘C’ of FIG. 2 according to one embodiment;

FIG. 4 is a view illustrating a connection relation between a plurality of touch blocks and a plurality of touch lines according to one embodiment;

FIG. 5 is a view illustrating a connection relation between a plurality of touch lines and a plurality of touch sensors in one touch block according to one embodiment;

FIG. 6 is a cross-sectional view illustrating an example of line I-I′ of FIG. 3 according to one embodiment;

FIG. 7 is a cross-sectional view illustrating an example of a first substrate and a second substrate, which are bonded to each other according to one embodiment;

FIG. 8 is a cross-sectional view illustrating a modified embodiment of FIG. 6 according to one embodiment;

FIG. 9 is an enlarged view illustrating an area ‘B’ of FIG. 1 according to one embodiment;

FIG. 10 is a cross-sectional view illustrating an example of line II-II′ of FIG. 9 according to one embodiment;

FIG. 11 is a cross-sectional view illustrating another example of line II-II′ of FIG. 8 according to one embodiment; and

FIG. 12 is a cross-sectional view illustrating another example of line II-II′ of FIG. 9 according to one embodiment.

### DETAILED DESCRIPTION

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, dimensions (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a situation where “comprise,” “have,” and “include” described in the present specification are used, another part can be added unless “only” is used. The terms of a singular form can include plural forms unless referred to the contrary.

In construing an element, the element is construed as including an error range although there is no explicit description.

In describing a position relationship, for example, when the position relationship is described as “upon˜,” “above˜,” “below,” and “next to,” one or more portions can be arranged between two other portions unless “just” or “direct” is used.

It will be understood that, although the terms “first,” “second,” etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., can be used. These terms are intended to identify the corresponding elements from the other elements, and basis, order, or number of the corresponding elements are not limited by these terms. The expression that an element is “connected” or “coupled” to another element should be understood that the element can directly be connected or coupled to another element but can directly be connected or coupled to another element unless specially mentioned, or a third element can be interposed between the corresponding elements.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship and are combinable.

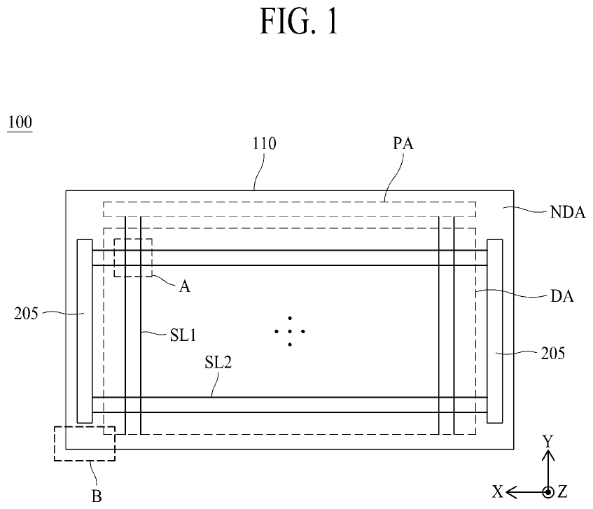

FIG. 1 is a schematic plan view illustrating a transparent display panel according to one embodiment.

Hereinafter, X axis indicates a line parallel with a scan line, Y axis indicates a line parallel with a data line, and Z axis indicates a height direction of a transparent display device 100.

Referring to FIG. 1, a transparent display device according to one embodiment of the present disclosure includes a transparent display panel 110. The transparent display panel 110 can include a display area DA provided with pixels to display an image, and a non-display area NDA for not displaying an image.

The display area DA can be provided with first signal lines SL1, second signal lines SL2 and the pixels. The non-display area NDA can be provided with a pad area PA in which pads are disposed, and at least one gate driver 205.

The first signal lines SL1 can be extended in a first direction (e.g., Y-axis direction). The first signal lines SL1 can cross the second signal lines SL2 in the display area DA. The second signal lines SL2 can be extended in the display area DA in a second direction (e.g., X-axis direction). The pixel can be provided in an area where at least one of the first signal line SL1 and the second signal line SL2 is provided, and emits predetermined light to display an image.

The gate driver 205 is connected to the scan lines and supplies scan signals to the scan lines. The gate driver 205 can be disposed in the non-display area NDA on one side or both sides of the display area DA of the transparent display panel 110 by a gate driver in panel (GIP) method or a tape automated bonding (TAB) method.

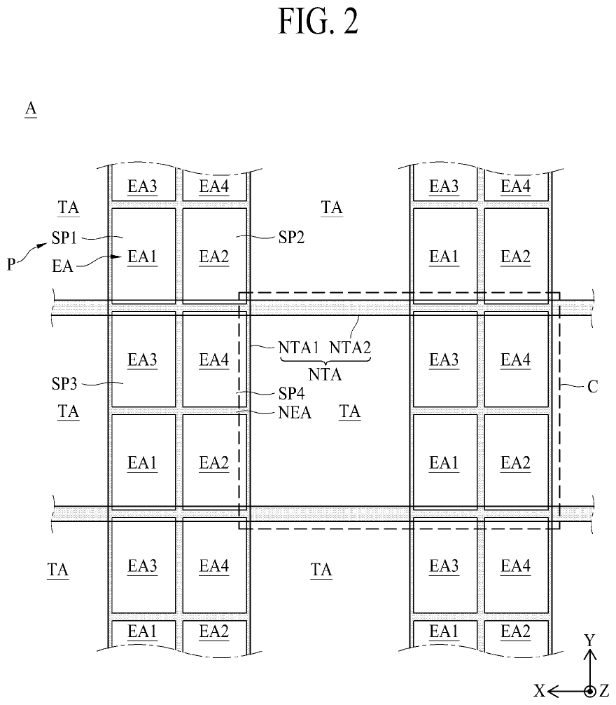

The transparent display panel 110 can further include a touch line and a touch sensor in addition to the first signal line SL1, the second signal line SL2 and the pixel in order to implement a touch function. A detailed description of the touch line and the touch sensor will be described later with reference to FIGS. 2 to 8.

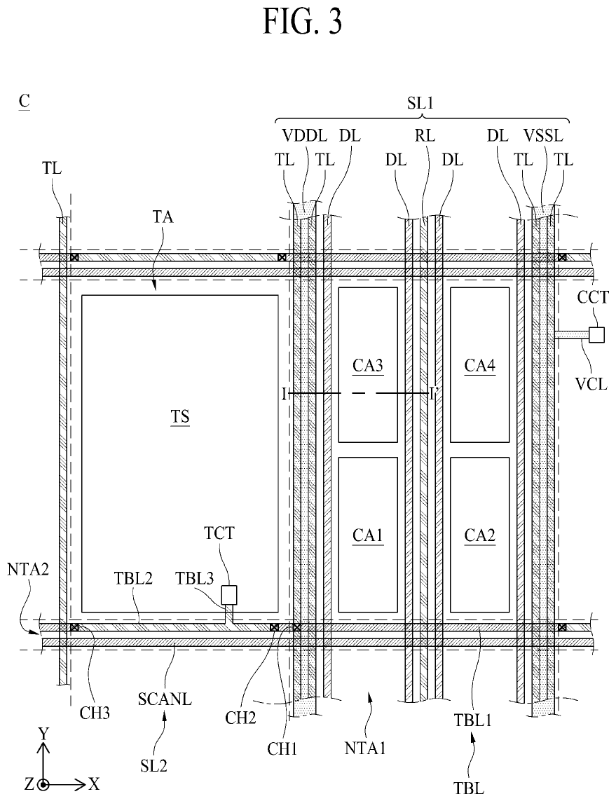

FIG. 2 is a schematic view illustrating an example of a pixel provided in an area ‘A’ of FIG. 1 according to one embodiment, and FIG. 3 is a view illustrating an example of signal lines, touch lines and a touch sensor, which are provided in an area ‘C’ of FIG. 2 according to one embodiment.

The display area DA, as shown in FIGS. 2 and 3, includes a transmissive area TA and a non-transmissive area NTA. The transmissive area TA is an area in which most of the externally incident light passes through, and the non-transmissive area NTA is an area through which most of the externally incident light fails to transmit through. For example, the transmissive area TA can be an area where light transmittance is greater than a %, and the non-transmissive area NTA can be an area where light transmittance is less than ß%, where a is greater than B. A user can view an object or background arranged at a rear surface of the transparent display panel 110 (e.g., behind the display panel) due to the transmissive area TA.

The non-transmissive area NTA can include a first non-transmissive area NTA1, a second non-transmissive area NTA2 and a plurality of pixels P. Pixels P can be provided to at least partially overlap with at least one of the first signal line SL1 and the second signal line SL2, thereby emitting predetermined light to display an image. A light emission area EA can correspond to an area, from which light is emitted, in the pixel P.

Each of the pixels P, as shown in FIG. 2, can include at least one of a first subpixel SP1, a second subpixel SP2, a third subpixel SP3, and a fourth subpixel SP4. The first subpixel SP1 can include a first light emission area EA1 emitting light of a first color. The second subpixel SP2 can include a second light emission area EA2 emitting light of a second color. The third subpixel SP3 can include a third light emission area EA3 emitting light of a third color. The fourth subpixel SP4 can include a fourth light emission area EA4 emitting light of a fourth color.

The first to fourth light emission area EA1, EA2, EA3 and EA4 can emit light of different colors. For example, the first light emission area EA1 can emit light of a green color. The second light emission area EA2 can emit light of a red color. The third light emission area EA3 can emit light of a blue color. The fourth light emission area EA4 can emit light of a white color. However, the light emission areas are not limited to this example. Also, the arrangement order of the subpixels SP1, SP2, SP3 and SP4 can be changed in various ways.

The first non-transmissive area NTA1 can be extended in a first direction (e.g., Y-axis direction) in a display area DA, and can be disposed to at least partially overlap light emission areas EA1, EA2, EA3 and EA4. A plurality of first non-transmissive areas NTA1 can be provided in the transparent display panel 110, and the transmissive area TA can be provided between two adjacent first non-transmissive areas NTA1. In the first non-transmissive area NTA1, first signals lines SL1 extended in the first direction (e.g., Y-axis direction) can be disposed to be spaced apart from each other.

For example, the first signal lines SL1 can include at least one of a pixel power line VDDL, a common power line VSSL, a reference line RL, and data lines DL.

The pixel power line VDDL can supply a first power source to a driving transistor DTR of each of subpixels SP1, SP2, SP3 and SP4 provided in the display area DA.

The common power line VSSL can supply a second power source to a cathode electrode of the subpixels SP1, SP2, SP3 and SP4 provided in the display area DA. At this time, the second power source can be a common power source commonly supplied to the subpixels SP1, SP2, SP3 and SP4.

The common power line VSSL can supply the second power source to the cathode electrode through a cathode contact electrode CCT. The cathode contact electrode CCT can be provided between the transmissive area TA and the common power line VSSL. A power connection line VCL can be disposed between the common power line VSSL and the cathode contact electrode CCT. One end of the power connection line VCL can be connected to the common power line VSSL and the other end thereof can be connected to the cathode contact electrode CCT. The cathode electrode can be connected to the cathode contact electrode CCT. As a result, the cathode electrode can be electrically connected to the common power line VSSL through the power connection line VCL and the cathode contact electrode CCT.

The reference line RL can supply an initialization voltage (or reference voltage) to the driving transistor DTR of each of the subpixels SP1, SP2, SP3 and SP4 provided in the display area DA. The reference line RL can be disposed between the plurality of data lines DL. For example, the reference line RL can be disposed at the center of the four data lines DL, that is, between the second data line DL and the third data line DL.

The reference line RL can be diverged and connected to the plurality of subpixels SP1, SP2, SP3 and SP4. In detail, the reference line RL can be connected to circuit elements of the plurality of subpixels SP1, SP2, SP3 and SP4 to supply an initialization voltage (or reference voltage) to each of the subpixels SP1, SP2, SP3 and SP4.

Each of the data lines DL can supply a data voltage to the subpixels SP1, SP2, SP3 and SP4. For example, one data line DL can supply a first data voltage to a first driving transistor of the first subpixel SP1, the other data line DL can supply a second data voltage to a second driving transistor of the second subpixel SP2. Another data line DL can supply a third data voltage to a third driving transistor of the third subpixel SP3 and another data line DL can supply a fourth data voltage to a fourth driving transistor of the fourth subpixel SP4.

The first signal lines SL1 can further include touch lines TL. In the transparent display panel 110 according to one embodiment of the present disclosure, the touch line TL can be further disposed in the first non-transmissive area NTA1. At least two touch lines TL can be provided in the first non-transmissive area NTA1. When the plurality of touch lines TL are disposed in the transmissive area TA of the transparent display panel 110, light transmittance may be deteriorated or impaired due to the plurality of touch lines TL.

Also, a slit, specifically an elongated linear or rectangular shape, can be provided between the plurality of touch lines TL. When external light passes through the slit, a diffraction phenomenon can occur. According to the diffraction phenomenon, light corresponding to plane waves can be changed to spherical waves as the light passes through the slit, and an interference phenomenon can occur in the spherical waves. Therefore, constructive interference and destructive interference occur in the spherical waves, whereby the external light that has passed through the slit can have irregular light intensity. As a result, in the transparent display panel 110, the definition or clarity of an object or image positioned at an opposite side may be reduced or impaired (e.g., it may appear slightly fuzzy or cloudy). For this reason, there are some technical benefits to dispose the plurality of touch lines TL in the first non-transmissive area NTA1 rather than the transmissive area TA.

A plurality of touch lines TL can be disposed between first signal lines SL1 in the first non-transmissive area NTA1 and a transmissive area TA as shown in FIG. 3. For example, four touch lines TL can be disposed in one first non-transmissive area NTA1. Two touch lines TL can be disposed between the circuit areas CA1, CA2, CA3, and CA4 and the transmissive area TA disposed on the right of the circuit areas CA1, CA2, CA3, and CA4. The other two touch lines TL can be disposed between the circuit areas CA1, CA2, CA3, and CA4 and the transmissive area TA disposed on the left of the circuit areas CA1, CA2, CA3, and CA4, but are not limited to this arrangement. The plurality of touch lines TL are formed to not overlap with circuit areas CA1, CA2, CA3, and CA4 in which circuit elements are disposed, and various modifications can be made in the arrangement order of the plurality of touch lines TL with the first signal lines SL1.

Further, the transparent display panel 110 includes a pixel P between adjacent transmissive areas TA. In particular, the pixel P can include light emission areas EA1, EA2, EA3, and EA4 in which a light emitting element is disposed to emit light. Because the non-transmissive area NTA in the transparent display panel 110 has a small area, a circuit element can be disposed to at least partially overlap the light emission areas EA1, EA2, EA3 and EA4.

Further, the touch lines TL do not overlap the circuit areas CA1, CA2, CA3, and CA4, whereby a parasitic capacitance of the touch lines TL due to the circuit elements can be reduced or minimized. Also, the transparent display panel 110 according to an embodiment of the present disclosure can reduce a horizontal distance difference between the touch lines TL and improve uniformity of the parasitic capacitance.

In addition, the second non-transmissive area NTA2 extends in the display area DA in a second direction (e.g., X-axis direction), and can be disposed to at least partially overlap the light emission areas EA1, EA2, EA3, and EA4. A plurality of second non-transmissive areas NTA2 can be provided in the transparent display panel 110, and the transmissive area TA can be provided between two adjacent second non-transmissive areas NTA2. Also, the second signal line SL2 can be disposed in the second non-transmissive area NTA2.

As shown in FIG. 3, the second signal line SL2 extends in a second direction (e.g., X-axis direction), and can include, for example, a scan line SCANL. The scan line SCANL can supply a scan signal to subpixels SP1, SP2, SP3, and SP4 of the pixel P.

In addition, the second signal line SL2 can further include a touch bridge line TBL. The touch bridge line TBL can connect any one of the touch lines TL with a touch sensor TS. The touch bridge line TBL can be connected to any one of the touch lines TL through a first contact hole CH1. The touch bridge line TBL can be connected to at least two touch sensors TS arranged in the second direction (e.g., X-axis direction) while extending in the second direction (e.g., X-axis direction).

Further, the touch lines TL can be disposed in the first non-transmissive area NTA1 that is not the second non-transmissive area NTA2, whereby the light transmittance can be prevented from being deteriorated due to the touch lines TL. In addition, as shown in FIG. 3, the second non-transmissive area NTA2 extended in the second direction (e.g., X-axis direction) crosses between adjacent transmissive areas TA. Also, when a width of the second non-transmissive area NTA2 crossing the transmissive areas TA is increased, a size of the transmissive area TA is reduced.

In addition, when the touch lines TL are disposed in the second non-transmissive area NTA2, the width of the second non-transmissive area NTA2 is increased to include a larger number of lines, and the size of the transmissive area TA is reduced. Thus, the light transmittance of the transparent display panel 110 is reduced due to the touch lines TL.

Further, in one embodiment, the touch lines TL are disposed in the first non-transmissive area NTA1, and one touch bridge line TBL for connecting the touch sensors TS is provided in the second non-transmissive area NTA2. Therefore, the transparent display panel 110 according to one embodiment of the present disclosure can reduce or minimize the decrease in size of the transmissive area TA or decrease in light transmittance due to the touch lines TL and the touch bridge line TBL.

In addition, the touch sensor TS is provided in the transmissive area TA. In more detail, the touch sensor TS can be disposed in each transmissive area TA, and changes in capacitance during a user contact. A touch driver is also connected to the touch sensors TS through the touch lines TL to detect a change in the capacitance of the touch sensors TS. The touch sensors TS can also correspond to the pixels P in a one-to-one correspondence.

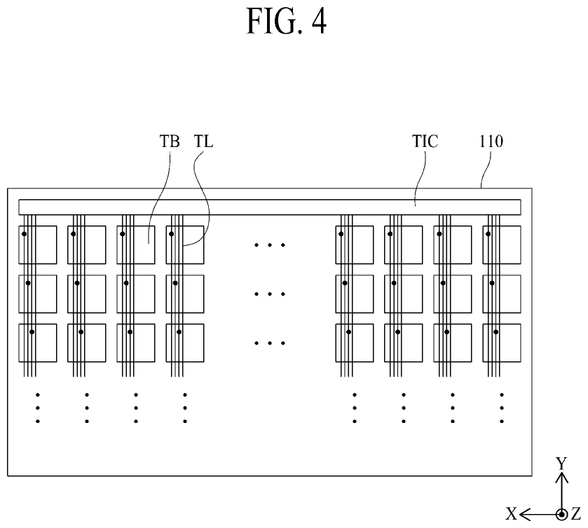

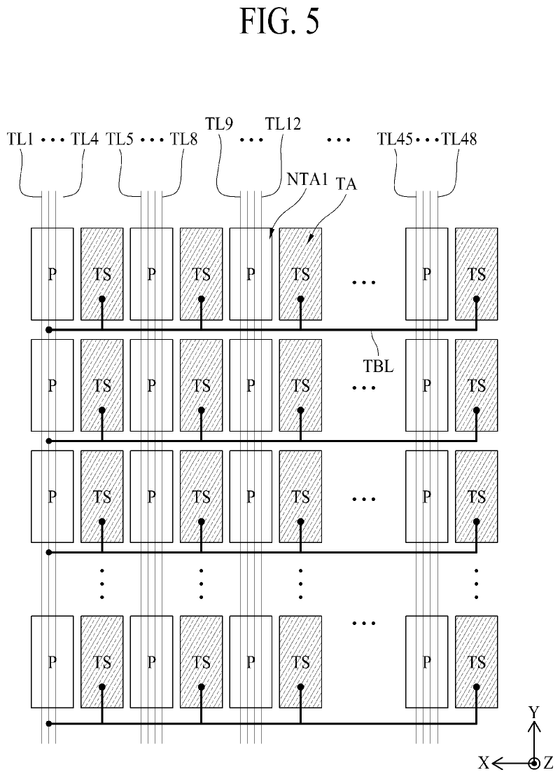

Hereinafter, a connection relationship among touch sensors TS, touch lines TL and touch bridge lines TBL will be described in more detail with reference to FIGS. 4 and 5. In particular, FIG. 4 is a view illustrating a connection relationship between a plurality of touch blocks and a plurality of touch lines according to one embodiment, and FIG. 5 is a view illustrating a connection relationship between a plurality of touch lines and a plurality of touch sensors in one touch block according to one embodiment.

Referring to FIGS. 4 and 5, the transparent display panel 110 includes a plurality of touch blocks TB. Each touch block TB includes a plurality of pixels P and a plurality of transmissive areas TA disposed to correspond to the pixels P one-to-one as a basic unit for determining a user touch position.

The transparent display panel 110 also includes touch sensors TS provided in each transmissive area TA. For example, each touch block TB can include 12×20 pixels P and 12×20 touch sensors TS. In this instance, when the image resolution is 1920×960, the touch resolution can be 160λ48.

Further, as each touch line TL is connected to one of the touch blocks TB, a change in capacitance of the touch sensors TS provided in the connected touch block TB can be sensed. That is, the touch lines TL provided in the transparent display panel 110 can correspond to the touch blocks TB in a one-to-one manner. Therefore, the number of touch lines TL can be the same as the number of touch blocks TB in the transparent display panel 110. For example, when the number of touch blocks TB is 160×48, the touch line TL can also be 160×48, and can be connected to the touch driver TIC.

As described above, to form the touch lines TL as much as the number of touch blocks TB, at least two touch lines TL are provided in one first non-transmissive area NTA1. For example, when an image resolution is 1920×960 and touch resolution is 160×48, four touch lines TL can be provided in one first non-transmissive area NTA1, as shown in FIG. 3, to form 160×48 touch lines TL in the transparent display panel 110.

As shown in FIG. 5, the touch sensors TS provided in one touch block TB can be connected to one of the touch lines TL provided in one touch block TB. For example, twelve first non-transmissive areas NTA1 can be provided in one touch block TB, and four touch lines TL can be disposed in each of the twelve first non-transmissive areas NTA1. As a result, one touch block TB can be provided with 48 touch lines TL1, . . . , TL48. In this instance, the touch sensors TS provided in one touch block TB can be connected to one specific touch line TL of the 48 touch lines TL1, . . . , TL48. In addition, the specific touch line TL can be connected to the touch sensors TS arranged in the second direction (e.g., X-axis direction) through the touch bridge lines TBL extending in the second direction (e.g., X-axis direction). As a result, the touch sensors TS provided in one touch block TB can be electrically connected to each other through the specific touch line TL and the touch bridge lines TBL.

In addition, each touch line TL can correspond to the touch blocks TB in a one-to-one manner. Therefore, the touch blocks TB are connected to different touch lines TL and thus can be electrically separated from each other. Further, each touch line TL can connect a plurality of touch sensors TS provided in a corresponding touch block TB to a touch driver TIC. In more detail, each touch line TL can transmit the changed capacitance provided from the touch sensors TS in the touch block TB to the touch driver TIC. The touch driver TIC can thus sense the changed capacitance, and can determine a user touch position. Also, each touch line TL can provide the touch sensing voltage generated from the touch driver TIC to the touch sensors TS provided in the touch block TB.

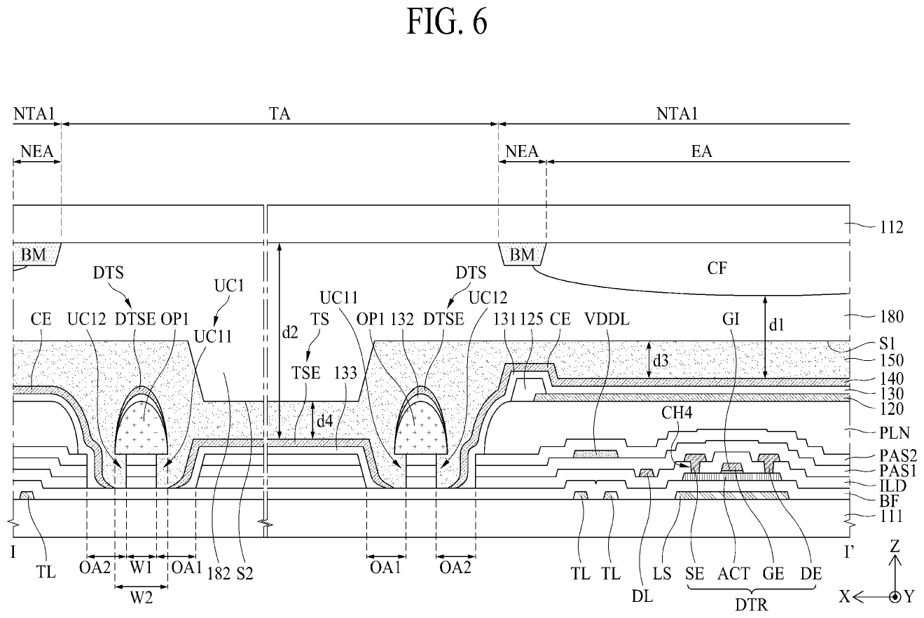

Next, the light emitting elements of the light emission areas EA, and the touch sensors TS of the transmissive area TA will be described in more detail with reference to FIG. 6. In particular, FIG. 6 is a cross-sectional view illustrating an example of line I-I′ of FIG. 3 according to one embodiment.

Referring to FIGS. 3, 6 and 7, the first substrate 111 can include transmissive areas TA and a non-transmissive area NTA including light emission area EA disposed between adjacent transmissive areas TA. The non-transmissive area NTA can include a first non-transmissive area NTA1 extending in the first direction (e.g., Y-axis direction) and a second non-transmissive area NTA2 extending in the second direction (e.g., X-axis direction).

The first non-transmissive area NTA1 includes circuit areas CA1, CA2, CA3 and CA4 in which at least one transistor and a capacitor are disposed. In addition, the first non-transmissive area NTA1 can include a pixel power line VDDL, a common power line VSSL, a reference line RL, data lines DL, touch lines TL extending in the first direction (e.g., Y-axis direction) and not overlapping the circuit areas CA1, CA2, CA3 and CA4. The second non-transmissive area NTA2 can include a scan line SCANL and a touch bridge line TBL extending in the second direction (e.g., X-axis direction).

The at least one transistor can include a driving transistor DTR and switching transistors. In particular, the switching transistor is switched in accordance with a scan signal supplied to the scan line SCANL to charge a data voltage supplied from the data line DL in the capacitor.

In addition, the driving transistor DTR is switched in accordance with the data voltage charged in the capacitor to generate a data current from a power source supplied from the pixel power line VDDL and to supply the data current to a first electrode layer 120 of the subpixels SP1, SP2, SP3, and SP4. The driving transistor DTR also includes an active layer ACT, a gate electrode GE, a source electrode SE, and a drain electrode DE.

In more detail, as shown in FIG. 6, a light shielding layer LS is provided on a first substrate 111. The light shielding layer LS shields external light incident on the active layer ACT in an area in which the driving transistor DTR is provided. The light shielding layer LS can include a single layer or multi-layer made of any one of molybdenum (Mo), aluminum (Al), chromium (Cr), gold (Au), titanium (Ti), nickel (Ni), neodymium (Nd) and copper (Cu), or their alloy.

Further, at least a portion of the pixel power line VDDL, the common power line VSSL, the reference line RL, the data lines DL, the touch lines TL, the touch bridge line TBL can be formed in the same layer as the light shielding layer LS. For example, the reference line RL, the touch lines TL, the touch bridge line TBL can include the same material as that of the light shielding layer LS in the same layer as the light shielding layer LS, but are not limited thereto.

A buffer layer BF can be provided over the light shielding layer LS. and the buffer layer BF protects the transistors DTR from water permeated through the first substrate 111, which is vulnerable to water permeation, and can include an inorganic layer, for example, a silicon oxide layer (SiOx), a silicon nitride layer (SiNx) or a multi-layer of the silicon oxide layer and the silicon nitride layer.

An active layer ACT of the driving transistor DTR can be provided over the buffer layer BF. In particular, the active layer ACT can include a silicon-based semiconductor material or an oxide-based semiconductor material. For example, the active layer ACT can include Indium Gallium Zinc Oxide IGZO. The active layer ACT can also include a multi-layer such as a first layer formed of a silicon-based semiconductor material or an oxide-based semiconductor material, and a second layer formed of ITO or IZO. For example, the active layer ACT of the driving transistor DTR can include a first layer made of Indium Gallium Zinc Oxide IGZO and a second layer made of IZO.

In addition, a gate insulating layer GI can be provided over the active layer ACT of the driving transistor DTR. In particular, the gate insulating layer GI can be provided in a pattern in the area where a gate electrode GE of the driving transistor DTR is disposed. The gate insulating layer GI can include an inorganic layer, for example, a silicon oxide layer (SiOx), a silicon nitride layer (SiNx) or a multi-layer of the silicon oxide layer and the silicon nitride layer.

Also, as shown in FIG. 6, the gate electrode GE of the driving transistor DTR can be provided over the gate insulating layer GI. The gate electrode GE can include a single layer or multi-layer made of one of molybdenum (Mo), aluminum (Al), chromium (Cr), gold (Au), titanium (Ti), nickel (Ni), neodymium (Nd) and copper (Cu), or their alloy.

An interlayer insulating layer ILD can be provided over the gate electrode GE1 of the driving transistor DTR. The interlayer insulating layer ILD can be provided in the non-transmissive area NTA and the transmissive area TA. However, to form a first undercut structure UC1 in the transmissive area TA, the interlayer insulating layer ILD includes an opened area, which exposes the buffer layer BF, without being provided in at least a portion of the transmissive area TA.

As an example, one or a plurality of first undercut structures UC1 can be provided. For example, the interlayer insulating layer ILD can include one opening area OA1 to form one undercut UC11 by using the first undercut structure UC1. Alternatively, the interlayer insulating layer ILD can include two or more opening areas OA1 and OA2 to form at least two or more undercuts UC11 and UC12 by using the first undercut structure UC1.

In the following description, for convenience of description, as shown in FIG. 6, the interlayer insulating layer ILD can include a first opening area OA1 and a second opening area OA2 to form two undercuts UC11 and UC12, but the present disclosure is not limited thereto. The interlayer insulating layer ILD can include an inorganic layer, for example, a silicon oxide layer (SiOx), a silicon nitride layer (SiNx) or their multi-layer.

In addition, a source electrode SE and a drain electrode DE of the driving transistor DTR can be disposed over the interlayer insulating layer ILD. In more detail, the source electrode SE1 and the drain electrode DE can be connected to the active layer ACT of the driving transistor DTR through a fourth contact hole CH4 passing through the interlayer insulating layer ILD. Also, the source electrode SE and the drain electrode DE can include a single layer or multi-layer made of any one of molybdenum (Mo), aluminum (Al), chromium (Cr), gold (Au), titanium (Ti), nickel (Ni), neodymium (Nd), and copper (Cu) or their alloy.

Further, at least a portion of the pixel power line VDDL, the common power line VSSL, the reference line RL, the data lines DL, the touch lines TL, the touch bridge line TBL can be provided on the same layer as the source electrode SE and the drain electrode DE of the driving transistor DTR. For example, the data lines DL can include the same material on the same layer as the source electrode SE and the drain electrode DE, but are not limited thereto.

A first passivation layer PAS1 for insulating the driving transistor DTR can be provided over the source electrode SE and the drain electrode DE of the driving transistor DTR. The first passivation layer PAS1 can be provided in the non-transmissive area NTA and the transmissive area TA. However, to form the first undercut structure UC1 in the transmissive area TA, the first passivation layer PAS1 can be provided with an opening area exposing the buffer layer BF, without being provided in at least a portion of the transmissive area TA.

In more detail, the first passivation layer PAS1 can be provided with a first opening area OA1 and a second opening area OA2, which expose the buffer layer BF without being provided in at least a portion of the transmissive area TA, to form two undercuts UC11 and UC12 by using the first undercut structure UC1 in the transmissive area TA. The first opening area OA1 of the first passivation layer PAS1 can at least partially overlap the first opening area OA1 of the interlayer insulating layer ILD. The second opening area OA2 of the first passivation layer PAS1 can at least partially overlap the second opening area OA2 of the interlayer insulating layer ILD. The first passivation layer PAS1 can include an inorganic layer, for example, a silicon oxide layer (SiOx), a silicon nitride layer (SiNx) or their multi-layer.

A second passivation layer PAS2 may be provided over the first passivation layer PAS1. The second passivation layer PAS2 may be provided in the non-transmissive area NTA and the transmissive area TA. In order to form the first undercut structure UC1 in the transmissive area TA, the second passivation layer PAS2 may be provided with an opening area, which exposes the buffer layer BF, without being provided in at least a portion of the transmissive area TA. In detail, the second passivation layer PAS2 may be provided with a first opening area OA1 and a second opening area OA2, which expose the buffer layer BF, without being provided in at least a portion of the transmissive area TA, in order to form two undercuts UC11 and UC12 in the transmissive area TA by using the first undercut structure UC1. The first opening area OA1 of the second passivation layer PAS2 may overlap the first opening area OA1 of the first passivation layer PAS1 and the first opening area OA1 of the interlayer insulating layer ILD, and the second opening area OA2 of the second passivation layer PAS2 may overlap the second opening area OA2 of the first passivation layer PAS1 and the second opening area OA2 of the interlayer insulating layer ILD. The second passivation layer PAS2 may be formed of an inorganic layer, for example, a silicon oxide layer (SiOx), a silicon nitride layer (SiNx) or their multi-layer.

A separate metal layer may be provided between the first passivation layer PAS1 and the second passivation layer PAS. At least a portion of the pixel power line VDDL, the common power line VSSL, the reference line RL, the data lines DL, the touch lines TL, the touch bridge line TBL may be formed in the metal layer.

For example, the pixel power line VDDL and the common power line VSSL may be formed between the first and second passivation layers PAS1 and PAS2. In this case, each of the pixel power line VDDL and the common power line VSSL may be provided to overlap a portion of the plurality of touch lines TL. The pixel power line VDDL may be provided to overlap two first touch lines TL disposed between circuit areas CA1, CA2, CA3, and CA4 and the transmissive area TA disposed at a right side of the circuit areas CA1, CA2, CA3, and CA4. The common power line VSSL may be provided to overlap two second touch lines TL disposed between the circuit areas CA1, CA2, CA3, and CA4 and the transmissive area TA disposed at a left side of the circuit areas CA1, CA2, CA3, and CA4.

In the transparent display panel 110 according to one embodiment of the present disclosure, the pixel power line VDDL and the common power line VSSL are provided to at least partially overlap the touch lines TL, whereby occurrence of parasitic capacitance may be blocked, minimized, or reduced between the touch lines TL and elements of the light emitting element, for example, a first electrode layer 120 and the cathode electrode CE. That is, the pixel power line VDDL and the common power line VSSL may serve as a shielding film for blocking parasitic capacitance that affects the touch lines TL.

The metal layer may be formed of a single layer or multi-layer made of any one of molybdenum (Mo), aluminum (Al), chromium (Cr), gold (Au), titanium (Ti), nickel (Ni), neodymium (Nd), copper (Cu), ITO and IZO, or their alloy. For example, the metal layer may be formed of an alloy of molybdenum (Mo) and titanium (Ti) or a stacked structure of an alloy of molybdenum (Mo) and titanium (Ti) and ITO or a stacked structure of an alloy of molybdenum (Mo) and titanium (Ti), copper (Cu) and ITO.

A planarization layer PLN for planarizing a step difference due to the driving transistor DTR and a plurality of signal lines may be provided on the second passivation layer PAS2. The planarization layer PLN may be provided in the non-transmissive area NTA, and may not be provided in at least a portion of the transmissive area TA. The planarization layer PLN may suppress transparency by inducing refraction or the like of light while transmitting light. Therefore, the transparent display panel 110 according to one embodiment of the present disclosure may increase transparency by removing a portion of the planarization layer PLN in the transmissive area TA.

The planarization layer PLN can include an organic layer such as acryl resin, epoxy resin, phenolic resin, polyamide resin, polyimide resin or the like.

In the transparent display panel 110 according to one embodiment of the present disclosure, the first undercut structure UC1 may be formed using a first organic pattern OP1 and a plurality of inorganic insulating layers.

In detail, the first undercut structure UC1 can include a first organic pattern OP1 and a plurality of inorganic layers that include a first opening area OA1 and a second opening area OA2. The first organic pattern OP1 may be formed of the same material as that of the planarization layer PLN on the same layer as the planarization layer PLN. The first organic pattern OP1 can be spaced apart from the planarization layer PLN provided in the non-transmissive area NTA, but is not necessarily limited thereto. The first organic pattern OP1 can be formed of a material different from that of the planarization layer PLN on a different layer from the planarization layer PLN. The plurality of inorganic layers may be the first and second passivation layers PAS1 and PAS2 and the interlayer insulating layer ILD.

The first organic pattern OP1 can be provided over the plurality of inorganic layers provided between the first opening area OA1 and the second opening area OA2. The first opening area OA1 of the plurality of inorganic layers can have a closed shape on a plane along an edge area of the touch sensor TS. For example, the first opening area OA1 of the plurality of inorganic layers can have a rectangular shape on a plane, but is not limited thereto.

The second opening area OA2 of the plurality of inorganic layers can be provided between the first opening area OA1 and the non-transmissive area NTA. The second opening area OA2 of the plurality of inorganic layers can be spaced apart from the first opening area OA1, and may have a closed shape on a plane along an outer edge of the first opening area OA1. For example, the second opening area OA2 of the plurality of inorganic layers can have a rectangular shape on a plane, but is not limited thereto.

Therefore, the plurality of inorganic layers provided between the first opening area OA1 and the second opening area OA2 can be separated from the plurality of inorganic layers, which are provided in an area overlapped with the touch sensor TS, with the first opening area OA1 interposed therebetween. In addition, the plurality of inorganic layers provided between the first opening area OA1 and the second opening area OA2 can be separated from the plurality of inorganic layers, which are provided in an area overlapped with the plurality of subpixels SP1, SP2, SP3 and SP4, with the second opening area OA2 interposed therebetween.

The first organic pattern OP1 can be provided over the plurality of inorganic layers provided between the first opening area OA1 and the second opening area OA2. The first organic pattern OP1 can be spaced apart from the plurality of inorganic layers provided in the area overlapped with the plurality of subpixels SP1, SP2, SP3, and SP4 and the plurality of inorganic layers provided in the area overlapped with the touch sensor TS. The first organic pattern OP1 can be provided on the entire upper surface of the plurality of inorganic layers provided between the first opening area OA1 and the second opening area OA2. The first organic pattern OP1 can has a second width W2 on the upper surface of the plurality of inorganic layers provided between the first opening area OA1 and the second opening area OA2, and may be formed along an outer area of the touch sensor TS. The first organic pattern OP1 can be a ring pattern having a closed shape on a plane. For example, the first organic pattern OP1 can be a ring pattern having a rectangular shape on a plane.

The plurality of inorganic layers provided between the first opening area OA1 and the second opening area OA2 can have a first width W1, and the first organic pattern OP1 can have a second width W2. The first undercut structure UC1 can be provided to have the second width W2 greater than the first width W1 of the plurality of inorganic layers. The first undercut structure UC1 can include a first undercut UC11 formed in an area where the first organic pattern OP1 overlaps at least a portion of the first opening area OA1. In the first undercut structure UC1, the first organic pattern OP1 can protrude more than the plurality of inorganic layers, which are provided between the first opening area OA1 and the second opening area OA2, in the first opening area OA1 to form the first undercut UC11. In the first undercut UC11, the first organic pattern OP1 protrude more toward the touch sensor TS than the plurality of inorganic layers provided between the first opening area OA1 and the second opening area OA2. Therefore, the first undercut structure UC1 can expose at least a portion of a lower surface of the first organic pattern OP1 in the first opening area OA1, and can form a space from the buffer layer BF without being provided with the plurality of inorganic layers below the exposed lower surface.

Also, the first undercut structure UC1 can include a second undercut UC12 formed in an area where the first organic pattern OP1 overlaps at least a portion of the second opening area OA2. In the first undercut structure UC1, the first organic pattern OP1 can protrude more than the plurality of inorganic layers, which are provided between the first opening area OA1 and the second opening area OA2, in the second opening area OA2 to form the second undercut UC12. In the second undercut UC12, the first organic pattern OP1 can protrude more toward the non-transmissive area NTA than the plurality of inorganic layers provided between the first opening area OA1 and the second opening area OA2. Therefore, the first undercut structure UC1 can expose at least a portion of the lower surface of the first organic pattern OP1 In the second opening area OA2, and can form a space from the buffer layer BF without being provided with the plurality of inorganic layers below the exposed lower surface.

The first undercut structure UC1 can be provided in the transmissive area TA. In more detail, an undercut area UCA in which the first undercut structure UC1 is formed may be provided between the touch sensor TS and the non-transmissive area NTA. In addition, the undercut area UCA can have a closed shape on a plane. As an example, the undercut area UCA may be formed along the edge area of the transmissive area TA. In this case, the undercut area UCA can be provided to surround the touch sensor TS.

In the transparent display panel 110 according to one embodiment of the present disclosure, the first undercut structure UC1 can be formed using the plurality of inorganic insulating layers and the first organic pattern OP1 including a transparent material, whereby light transmittance can be prevented from being reduced due to the first undercut structure UC1.

The first electrode layer 120, an organic light emitting layer 130, a second electrode layer 140, and a bank 125 can be provided over the planarization layer PLN.

The first electrode layer 120 can be provided for each of the subpixel SP1, SP2, SP3 and SP4 over the planarization layer PLN. The first electrode layer 120 can be not provided in the transmissive area TA. The first electrode layer 120 can be connected to the driving transistor DTR. In detail, the first electrode layer 120 can be connected to one of the source electrode SE and the drain electrode DE of the driving transistor DTR through a contact hole (not shown) passing through the planarization layer PLN and the first and second passivation layers PAS1 and PAS2.

The first electrode layer 120 can include a metal material having high reflectance, such as a stacked structure (Ti/Al/Ti) of aluminum and titanium, a stacked structure (ITO/AI/ITO) of aluminum and ITO, an Ag alloy, a stacked structure (ITO/Ag alloy/ITO) of Ag alloy and ITO, a MoTi alloy, and a stacked structure (ITO/MoTi alloy/ITO) of MoTi alloy and ITO. The Ag alloy can be an alloy of silver (Ag), palladium (Pd), copper (Cu), etc. The MoTi alloy can be an alloy of molybdenum (Mo) and titanium (Ti). The first electrode layer 120 can be an anode electrode.

The bank 125 can be provided over the planarization layer PLN. The bank 125 can be provided to at least partially cover an edge of the first electrode layer 120 and expose a portion of the first electrode layer 120. Therefore, the bank 125 can prevent a problem in which light emitting efficiency is deteriorated due to the concentration of a current on an end of the first electrode layer 120.

Further, the bank 125 defines light emission areas EA1, EA2, EA3, and EA4 of the subpixels SP1, SP2, SP3 and SP4. In particular, the light emission areas EA1, EA2, EA3, and EA4 of each of the subpixels SP1, SP2, SP3, and SP4 represent an area in which the first electrode layer 120, the organic light emitting layer 130 and the cathode electrode CE are sequentially stacked and holes from the first electrode layer 120 and electrons from the cathode electrode CE are combined with each other in the organic light emitting layer 130 to emit light. In this instance, the area in which the bank 125 is provided can become the non-light emission area NEA because light is not emitted therefrom, and the area in which the bank 125 is not provided and the first electrode is exposed can become the light emission area EA. The bank 125 can also include an organic layer such as an acrylic resin, an epoxy resin, a phenolic resin, a polyamide resin, and a polyimide resin.

The organic light emitting layer 130 can be disposed over the first electrode layer 120. In more detail, the organic light emitting layer 130 can include a hole transporting layer, a light emitting layer and an electron transporting layer. In this instance, when a voltage is applied to the first electrode layer 120 and the cathode electrode CE, holes and electrons move to the light emitting layer through the hole transporting layer and the electron transporting layer, respectively and are combined with each other in the light emitting layer to emit light.

In one embodiment, the organic light emitting layer 130 can be a common layer commonly provided in the subpixels SP1, SP2, SP3 and SP4. In this instance, the light emitting layer can be a white light emitting layer for emitting white light.

In another embodiment, the light emitting layer of the organic light emitting layer 130 can be provided for each of the subpixels SP1, SP2, SP3 and SP4. For example, a green light emitting layer for emitting green light can be provided in the first subpixel SP1, a red light emitting layer for emitting red light can be provided in the second subpixel SP2, a blue light emitting layer for emitting blue light can be provided in the third subpixel SP3, and a white light emitting layer for emitting white light can be provided in the fourth subpixel SP4. In this instance, the light emitting layer of the organic light emitting layer 130 is not provided in the transmissive area TA.

In addition, an organic light emitting layer 130 can be separated from the non-transmissive area NTA and the transmissive area TA by the first undercut structure UC1. In more detail, the organic light emitting layer 130 can be separated from an organic light emitting layer 131 provided in the non-transmissive area NTA, an organic light emitting layer 132 provided on the first undercut structure UC1 and an organic light emitting layer 133 provided in the transmissive area TA by the first undercut structure UC1. That is, the organic light emitting layer 131 provided in the non-transmissive area NTA and the organic light emitting layer 133 provided in the transmissive area TA can be spaced apart from each other by the first undercut structure UC1.

A second electrode layer 140 can be disposed over the organic light emitting layer 130 and the bank 125. When the second electrode layer 140 is deposited on an entire surface, the second electrode layer 140 can be separated without being continuous between the non-transmissive area NTA and the transmissive area TA by the first undercut structure UC1. In more detail, the second electrode layer 140 can be separated into a second electrode CE provided in the non-transmissive area NTA, a second electrode DTSE provided on the first undercut structure UC1 and a second electrode TSE provided in the transmissive area TA by the first undercut structure UC1.

In this instance, the second electrode CE (hereinafter, referred to as ‘cathode electrode’) provided in the non-transmissive area NTA can be a cathode electrode, and is an element constituting a light emitting element. The cathode electrode CE can be connected to a cathode contact electrode CCT to receive a power source from the common power line VSSL. In addition, the cathode electrode CE can be a common layer that is commonly provided in the subpixels SP1, SP2, SP3 and SP4 to apply the same voltage.

Also, a second electrode TSE (hereinafter, referred to as ‘touch sensor electrode’) provided in the transmissive area TA can be a touch sensor electrode, and can constitute the touch sensor TS. The touch sensor electrode TSE can be connected to a touch contact electrode TCT to provide a change in capacitance to the touch line TL.

The touch sensor TS can be connected to the touch line TL through a touch contact electrode TCT and a touch bridge line TBL. The touch bridge line TBL can connect the touch contact electrode TCT with the touch line TL. The touch bridge line TB can include a first touch bridge line TBL1, a second touch bridge line TBL2 and a third touch bridge line TBL3 as shown in FIG. 3.

The first touch bridge line TBL1 can be disposed in an area where the first non-transmissive area NTA1 and the second non-transmissive area NTA2 cross each other, and may extend in the second direction (e.g., X-axis direction). One end of the first touch bridge line TBL1 can be connected to one second touch bridge line TBL2 through one second contact hole CH2, and the other end of the first touch bridge line TBL1 can be connected to another second touch bridge line TBL2 through a third contact hole CH3. The first touch bridge line TBL1 can be connected to one of the plurality of touch lines TL through a first contact hole CH1.

The first touch bridge line TBL1 can be disposed on a layer different from first signal lines SL1 extended in the first direction (e.g., Y-axis direction) in the first non-transmissive area NTA1. The first touch bridge line TBL1 can be disposed on the same layer as at least one of the light-shielding layer LS, the active layer ACT, the gate electrode GE, the source electrode SE or the drain electrode DE of the driving transistor DTR. For example, the first touch bridge line TBL1 can be disposed on the same layer as the gate electrode GE of the driving transistor DTR.

The second touch bridge line TBL2 can be provided in the second non-transmissive area NTA2 disposed between the transmissive areas TA. The second touch bridge line TBL2 can be electrically connected to the first touch bridge line TBL1 and then can be extended in the second direction (e.g., X-axis direction). In detail, one end of the second touch bridge line TBL2 can be connected to one first touch bridge line TBL1 through one second contact hole CH2, and the other end of the second touch bridge line TBL2 can be connected to the other first touch bridge line TBL1 through a third contact hole CH3.

The second touch bridge line TBL2 can be disposed on the same layer as at least one of the light-shielding layer LS, the active layer ACT, the gate electrode GE, the source electrode SE or the drain electrode DE of the driving transistor DTR. For example, the second touch bridge line TBL2 can be disposed on the same layer as the light-shielding layer LS.

The third touch bridge line TBL3 can electrically connect the touch contact electrode TCT with the second touch bridge line TBL2. The third touch bridge line TBL3 may be protruded from one side of the second touch bridge line TBL2 and extended to an area overlapped with the touch sensor TS. The third touch bridge line TBL3 can be electrically connected to the touch contact electrode TCT at one end.

The third touch bridge line TBL3 can be formed on a layer provided between the first substrate 111 and the driving transistor DTR. In one embodiment, the third touch bridge line TBL3 can be formed of the same material as that of the light-shielding layer LS on the same layer as the light-shielding layer LS. The third touch bridge line TBL3 can be extended to cross the first undercut structure UC1. The first undercut structure UC1 can be formed through a wet etching process. In the transparent display panel 110 according to one embodiment of the present disclosure, the third touch bridge line TBL3 can be formed on the same layer as the light-shielding layer LS so that the third touch bridge line TBL3 may be prevented from being lost during the wet etching process for forming the first undercut structure UC1.

The third touch bridge line TBL3 can be formed on the same layer as the second touch bridge line TBL2, but is not necessarily limited thereto. The third touch bridge line TBL3 can be formed in a layer different from the second touch bridge line TBL2. However, even in this case, it may be desirable that the third touch bridge line TBL3 is formed on a layer provided between the first substrate 111 and the driving transistor DTR.

The touch contact electrode TCT can be provided in the transmissive area TA. The touch contact electrode TCT can be disposed between the third touch bridge line TBL3 and the touch sensor electrode TSE to electrically connect the third touch bridge line TBL3 with the touch sensor electrode TSE. The touch contact electrode TCT can be connected to the third touch bridge line TBL3 through a contact hole.

In addition, at least a portion of an upper surface of the touch contact electrode TCT can be exposed by a second undercut structure (not shown), and the touch sensor electrode TSE can be connected to the exposed upper surface. In detail, the touch contact electrode TCT can be formed on a layer provided between the buffer layer BF and the second passivation layer PAS2. In one embodiment, the touch contact electrode TCT can be provided between the interlayer insulating layer ILD and the first passivation layer PAS1. That is, the touch contact electrode TCT can be provided on the same layer as the source electrode SE and the drain electrode DE of the driving transistor DTR.

In this case, the first and second passivation layers PAS1 and PAS2 can be provided with an opening area (not shown) formed to expose at least a portion of the upper surface of the touch contact electrode TCT. Therefore, the touch contact electrode TCT can be electrically connected to the touch sensor electrode TSE as the touch sensor electrode TSE is connected to the exposed upper surface of the touch contact electrode TCT. As a result, the touch sensor electrode TSE can be electrically connected to the touch line TL through the touch contact electrode TCT and the touch bridge line TBL.

Meanwhile, a second electrode DTSE (hereinafter, referred to as ‘dummy touch sensor electrode’) provided over the first undercut structure UC1 can be a dummy touch sensor electrode, and can constitute a dummy touch sensor DTS. The dummy touch sensor electrode DTSE can be not connected to the touch sensor TS, and does not serve as the touch sensor TS. The dummy touch sensor electrode DTSE can be provided between the touch sensor TS and the light emitting element so that the touch sensor electrode TSE of the touch sensor TS. The cathode electrode CE of the light emitting element can be more certainly separated from each other.

In addition, the second electrode layer 140, which includes the cathode electrode CE, the dummy touch sensor electrode DTSE and the touch sensor electrode TSE, can include a transparent conductive material (TCO) such as ITO and IZO that can transmit light, or a semi-transmissive conductive material such as magnesium (Mg), silver (Ag) or an alloy of magnesium (Mg) and silver (Ag). When the second electrode layer 140 includes a semi-transmissive conductive material, the light emitting efficiency can be increased by a micro cavity.

An encapsulation layer (not shown) can then be provided over the light emitting elements and the touch sensors TS. In particular, the encapsulation layer can be provided over the cathode electrode CE and the touch sensor electrode TSE to at least partially cover the cathode electrode CE and the touch sensor electrode TSE. The encapsulation layer serves to prevent oxygen or water from being permeated into the organic light emitting layer 130, the cathode electrode CE and the touch sensor electrode TSE. Accordingly, in some embodiments, the encapsulation layer can include at least one inorganic layer and at least one organic layer. The encapsulation layer can be omitted.

In addition, a color filter CF is then provided over one surface of the second substrate 112 facing the first substrate 111.

The color filter CF can be patterned for each of subpixels SP1, SP2, SP3, and SP4. In detail, the color filter CF can include a first color filter, a second color filter, a third color filter, and a fourth color filter. The first color filter can be disposed to correspond to an emission area EA1 of the first subpixel SP1, for example, a green color filter which transmits green light. The second color filter can be disposed to correspond to an emission area EA2 of the second subpixel SP2, for example, a red color filter which transmits red light. The third color filter can be disposed to correspond to an emission area EA3 of the third subpixel SP3, for example, a blue color filter which transmits blue light. The fourth color filter CF4 can be disposed to correspond to an emission area EA4 of the fourth subpixel SP4, for example, a white color filter which transmits white light. The white color filter can be formed of a transparent organic material which transmits white light, but not necessarily limited thereto.

A black matrix BM can be provided between each of the color filters CF. The black matrix BM can be provided between each of the subpixels SP1, SP2, SP3, and SP4, so that it is possible to prevent or at least reduce color mixture from occurring between the adjacent subpixels SP1, SP2, SP3, and SP4, and to prevent or at least reduce light incident from the outside from being reflected to a plurality of signal lines provided between the subpixels SP1, SP2, SP3, and SP4, for example, scan lines SCANL, data lines DL, pixel power lines VDDL, common power lines VSSL, reference lines RL, and the like.

Also, the black matrix BM is provided between the transmission area TA and the plurality of subpixels SP1, SP2, SP3, and SP4, thereby preventing or at least reducing light emitted from each of the plurality of subpixels SP1, SP2, SP3, and SP4 from proceeding to the transmission area TA. According to one embodiment of the present disclosure, the black matrix BM cannot be provided between the white subpixel and the transmission area TA. A display panel 110 according to one embodiment of the present disclosure does not include the black matrix BM between the white subpixel and the transmission area TA, thereby reducing a formation area of the black matrix BM. Accordingly, the display panel 110 according to one embodiment of the present disclosure can improve a transmittance. The black matrix BM can include a light absorbing material, for example, a black dye which absorbs light in a visible wavelength band.

A filler 150 can be provided between the first substrate 111 having light emitting elements and touch sensors TS and the second substrate 112 having the color filter CF and the black matrix BM. In this case, the filler 150 may be made of a thermosetting resin or a UV curable resin, and can include an organic material having an adhesive property. In one embodiment, the filler 150 can include a material that absorbs hydrogen.

An organic layer 180 can be further provided over one surface of the second substrate 112, which faces the first substrate 111. The organic layer 180 can be provided over a plurality of color filters CF and the black matrix BM to cover the plurality of color filters CF and the black matrix BM. The organic layer 180 can have a flat surface S1 while planarizing a step difference caused by the plurality of color filters CF and the black matrix BM.

In addition, the organic layer 180 can include a first protrusion pattern 182 protruded toward the touch sensor TS in the transmissive area TA. The first protrusion pattern 182 can be provided in an area overlapped with the touch sensor TS, and can be provided in an area surrounded by the first undercut structure UC1. The first protrusion pattern 182 can include a first convex surface S2 protruded from the flat surface S1 in an area overlapped with the touch sensor TS. The organic layer 180 can reduce a spaced distance from the touch sensor TS by the first protrusion pattern 182.

The first substrate 111 in which the light emitting elements and the touch sensors TS are provided can generate a large step difference between the light emitting elements and the touch sensors TS. This is because the first undercut structure UC1 including the opening areas OA1 and OA2 is provided near the touch sensors TS and the planarization layer PLN is not provided in an area overlapped with the touch sensors TS. As a result, the first substrate 111 can be formed such that its upper surface in the transmissive area TA, for example, an upper surface of the touch sensor electrode TSE can be very lower than its upper surface in the non-transmissive area NTA, for example, an upper surface of the cathode electrode CE.

In addition, the second substrate 112 in which the organic layer 180 is not provided can generate a step difference due to the plurality of color filters CF and the black matrix BM. This is because the second substrate 112 is provided with the plurality of color filters CF and the black matrix BM in the non-transmissive area NTA but is not provided with them in the transmissive area TA. As a result, the second substrate 112 can be formed such that its upper surface in the transmissive area TA, for example, one surface of the second substrate 112 can be very lower than its upper surface in the non-transmissive area NTA, for example, an upper surface of the plurality of color filters CF and the black matrix BM.

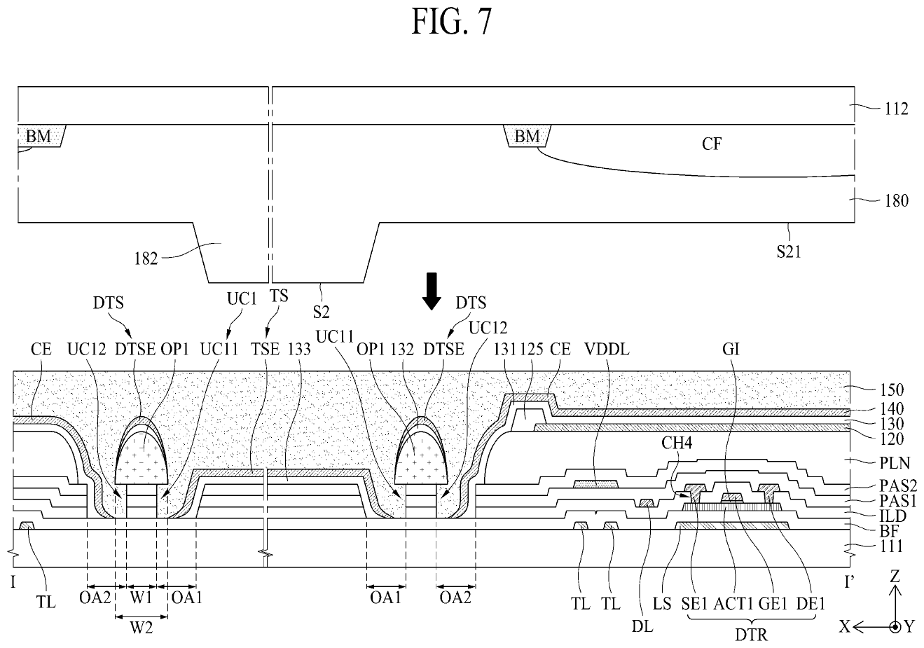

The first substrate 111 and the second substrate 112 can be formed through separate processes, respectively, as shown in FIG. 7. The light emitting elements and the touch sensors TS can be formed on the first substrate 111, and the plurality of color filters CF and the black matrix BM can be formed on the second substrate 112. Then, the first substrate 111 in which the light emitting elements and the touch sensors TS are provided and the second substrate 112 in which the color filters CF and the black matrix BM are provided can be bonded to each other with the filler 150 interposed therebetween. A spaced distance between the first substrate 111 and the second substrate 112 can have a great difference in the non-transmissive area NTA and the transmissive area TA. In the non-transmissive area NTA, a first spaced distance d1 can be formed between the upper surface of the cathode electrode CE of the first substrate 111 and the upper surface of the color filter CF of the second substrate 112. In the transmissive area TA, a second spaced distance d2 can be provided between the upper surface of the touch sensor electrode TSE of the first substrate 111 and one surface of the second substrate 112. The second spaced distance d2 can be very greater than the first spaced distance d1 as shown in FIG. 6.

As described above, when the first spaced distance d1 and the second spaced distance d2 have a great difference, an area in which the filler 150 is not filled can occur when the first substrate 111 and the second substrate 112 are bonded to each other. The filler 150 does not fill a space in the transmissive area TA, which has a great spaced distance between the first substrate 111 and the second substrate 112, whereby a non-filling area can occur.

In this case, a difference in visibility can occur between the area filled with the filler 150 and a non-filled area that is not filled with the filler 150. In a state that the transparent display panel 110 is not driven, a stain can be recognized, and even in a driving state of the transparent display panel 110, a strip-shaped stain can be recognized to suppress visibility.

In the transparent display panel 110 according to one embodiment of the present disclosure, the organic layer 180 is provided on the second substrate 112 in which the color filters CF and the black matrix BM are provided, whereby the step difference due to the color filters CF and the black matrix BM can be planarized. Therefore, the transparent display panel 110 according to one embodiment of the present disclosure can compensate for the step difference between the non-transmissive area NTA and the transmissive area TA, which is generated by the color filters CF and the black matrix BM on the second substrate 112.

Also, in the transparent display panel 110 according to one embodiment of the present disclosure, the organic layer 180 can be provided with the first protrusion pattern 182, so that the step difference between the non-transmissive area NTA and the transmissive area TA, which is generated on the first substrate 111, can be compensated. In the transparent display panel 110 according to one embodiment of the present disclosure, the first protrusion pattern 182 can be provided to be protruded toward the touch sensor electrode TSE formed at a height lower than that of the cathode electrode CE on the first substrate 111, whereby the spaced distance between the touch sensor electrode TSE and the organic layer 180 can be reduced.

Consequently, in the transparent display panel 110 according to one embodiment of the present disclosure, the organic layer 180 can be provided on the second substrate 112, whereby the spaced distance between the first substrate 111 and the second substrate 112 can be reduced. Furthermore, the transparent display panel 110 according to one embodiment of the present disclosure can reduce a difference between the spaced distance in the non-transmissive area NTA and the spaced distance in the transmissive area TA. In the non-transmissive area NTA, a third spaced distance d3 can be formed between the upper surface of the cathode electrode CE of the first substrate 111 and the flat surface S1 of the organic layer 180 of the second substrate 112. In the transmissive area TA, a fourth spaced distance d4 can be formed between the upper surface of the touch sensor electrode TSE of the first substrate 111 and the first convex surface S2 of the organic layer 180 of the second substrate 112. As shown in FIG. 6, the third spaced distance d3 can be smaller than the first spaced distance d1 and the fourth spaced distance d4 can be smaller than the second spaced distance d2. In addition, the difference between the third spaced distance d3 and the fourth spaced distance d4 can be reduced to be greater than the difference between the first spaced distance d1 and the second spaced distance d2.

In the transparent display panel 110 according to one embodiment of the present disclosure, since the difference between the third spaced distance d3 and the fourth spaced distance d4 is not great, when the first substrate 111 and the second substrate 112 are bonded to each other, the filler 150 can be uniformly spread and filled in the non-transmissive area NTA and the transmissive area TA. That is, the transparent display panel 110 according to one embodiment of the present disclosure can prevent an area, in which the filler 150 is not filled, from being generated. Therefore, the transparent display panel 110 according to one embodiment of the present disclosure can prevent or at least reduce occurrence of a stain or deterioration of visibility from being caused due to the filler 150.

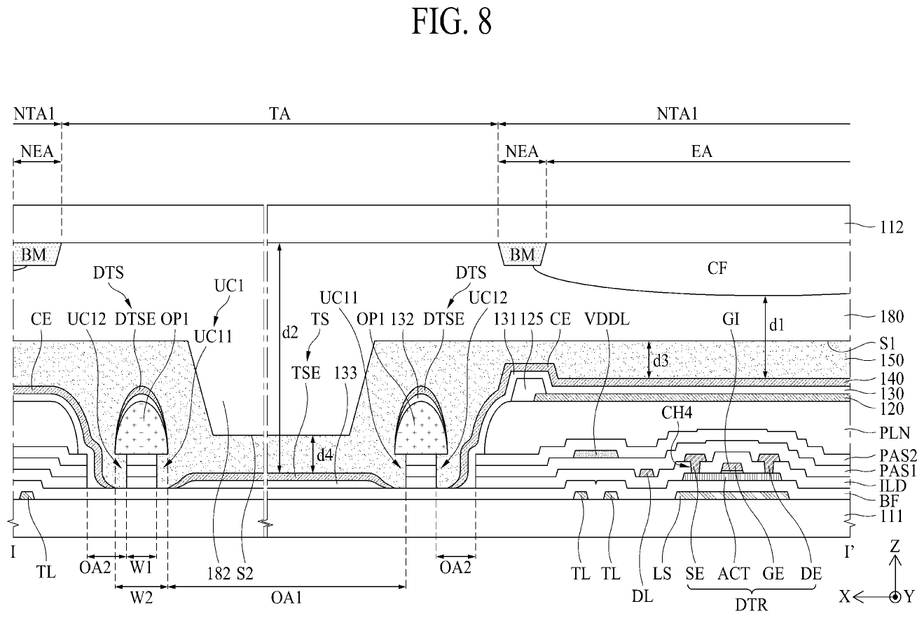

Meanwhile, FIGS. 6 and 7 show that the plurality of inorganic layers are provided in an area overlapped with the touch sensor TS, but the present disclosure is not limited thereto. In a modified embodiment, the plurality of inorganic layers, for example, the first and second passivation layers PAS1 and PAS2 and the interlayer insulating layer ILD cannot be provided in an area overlapped with the touch sensor TS as shown in FIG. 8. At this time, the first opening area OA1 of the plurality of inorganic layers can be provided to overlap the touch sensor TS, and can be provided to have an area wider than that of the touch sensor TS.

In this case, in the transparent display panel 110 according to the modified embodiment, the difference between the first spaced distance d1 in the non-transmissive area NTA and the second spaced distance d2 in the transmissive area TA can be more increased. In the transparent display panel 110 according to the modified embodiment, the organic layer 180 can be provided on the second substrate 112 to reduce the spaced distance between the first substrate 111 and the second substrate 112 and reduce the difference in the spaced distance between the non-transmissive area NTA and the transmissive area TA.

In the transparent display panel 110 according to the modified embodiment, the height of the first protrusion pattern 182 of the organic layer 180 can be adjusted to adjust the difference between the third spaced distance d3 in the non-transmissive area NTA and the fourth spaced distance d4 in the transmissive area TA. In the transparent display panel 110 according to the modified embodiment, the height of the first protrusion pattern 182 can be increased to reduce the difference between the third spaced distance d3 in the non-transmissive area NTA and the fourth spaced distance d4 in the transmissive area TA. Therefore, in the transparent display panel 110 according to the modified embodiment, when the first substrate 111 and the second substrate 112 are bonded to each other, the filler 150 can be uniformly spread and filled in the non-transmissive area NTA and the transmissive area TA. That is, the transparent display panel 110 according to one embodiment of the present disclosure can prevent the area, in which the filler 150 is not filled, from being generated. Therefore, the transparent display panel 110 according to the modified embodiment can also prevent occurrence of a stain or deterioration of visibility from being caused due to the filler 150.

In the transparent display panel 110 according to one embodiment of the present disclosure, the touch sensor electrode TSE of the touch sensor TS and the cathode electrode CE of the light emitting element can be formed on the same layer by using the first undercut structure UC1. In the transparent display panel 110 according to one embodiment of the present disclosure, a touch process can be simplified, and a separate mask for the touch sensor electrode TSE is not required additionally. Therefore, the transparent display panel 110 according to one embodiment of the present disclosure can implement process optimization and reduce production energy.

Also, in the transparent display panel 110 according to one embodiment of the present disclosure, the first undercut structure UC1 can be formed using the plurality of inorganic insulating layers and the first organic pattern OP1 made of a transparent material, whereby the first undercut structure UC1 can be formed without loss of light transmittance.

Also, in the transparent display panel 110 according to one embodiment of the present disclosure, the plurality of undercuts UC11 and UC12 can be formed using the first undercut structure UC1, so that the touch sensor electrode TSE of the touch sensor TS and the cathode electrode CE of the light emitting element can be more certainly separated from each other. Therefore, the transparent display panel 110 according to one embodiment of the present disclosure can reduce a defect rate generated as the touch sensor electrode TSE of the touch sensor TS and the cathode electrode CE of the light emitting element are connected to each other.

Also, in the transparent display panel 110 according to one embodiment of the present disclosure, the touch lines TL can be disposed below the light emitting element, so that emission efficiency of the pixel P can be prevented from being deteriorated due to the touch lines TL.

Also, in the transparent display panel 110 according to one embodiment of the present disclosure, the touch lines TL can be disposed so as not to overlap the circuit areas CA1, CA2, CA3 and CA4, whereby influence due to a circuit element can be minimized and at the same time uniformity of parasitic capacitance can be improved.

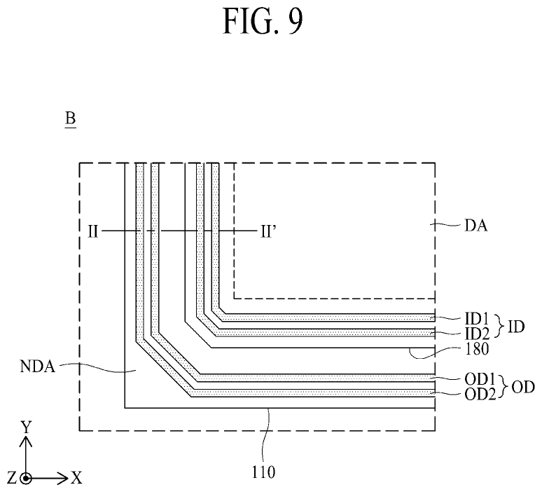

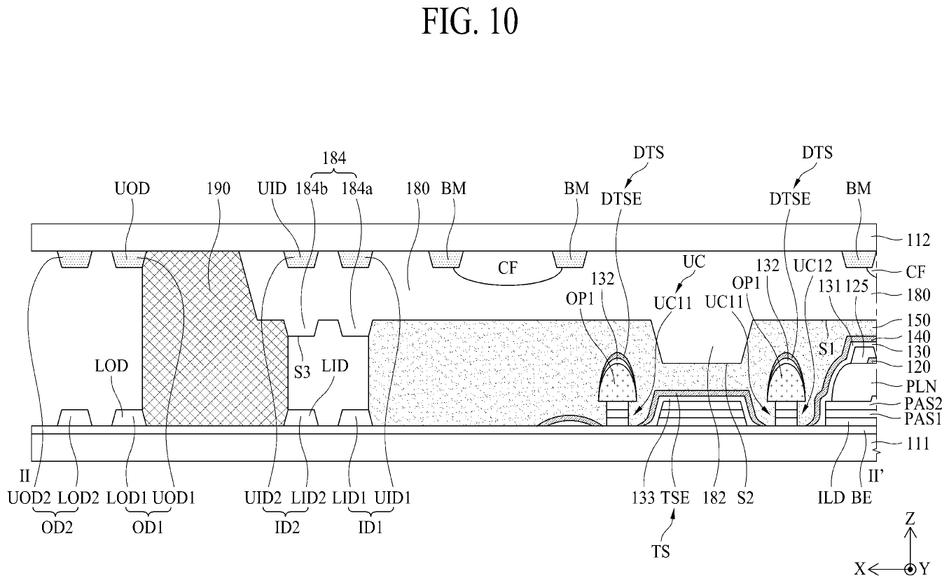

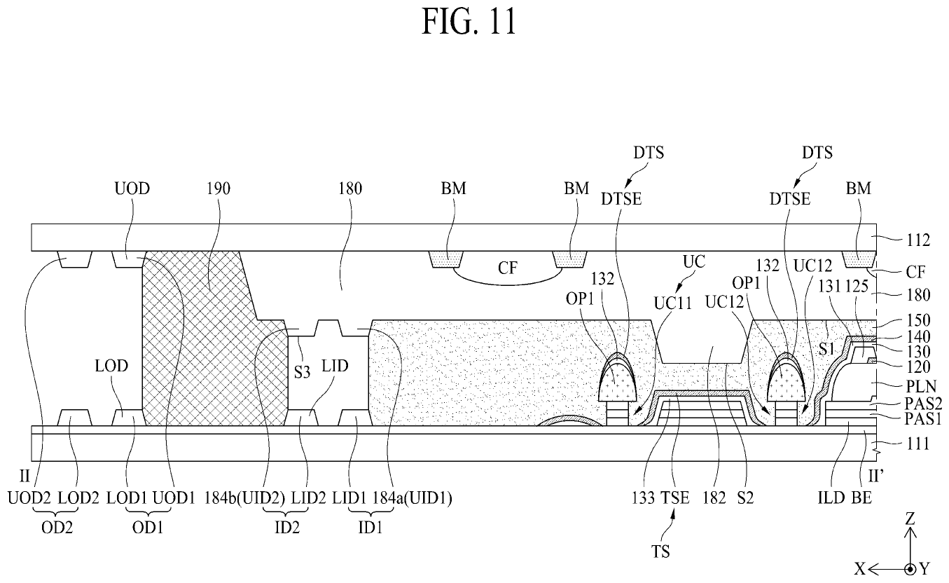

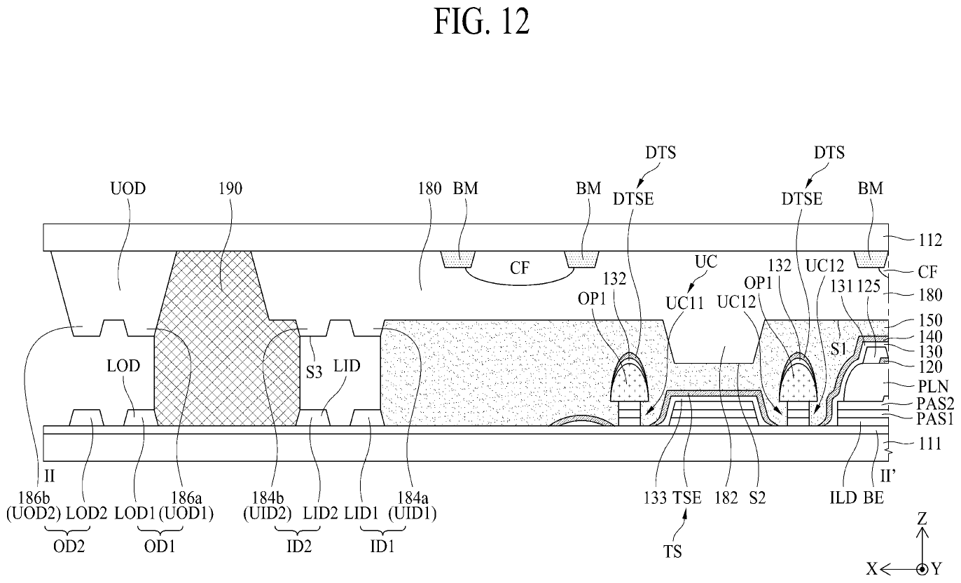

FIG. 9 is an enlarged view illustrating an area ‘B’ of FIG. 1 according to one embodiment, FIG. 10 is a cross-sectional view illustrating an example of line II-II′ of FIG. 9 according to one embodiment, FIG. 11 is a cross-sectional view illustrating another example of line II-II′ of FIG. 8 according to one embodiment, and FIG. 12 is a cross-sectional view illustrating another example of line II-II′ of FIG. 9 according to one embodiment.

Referring to FIGS. 9 to 12, the transparent display panel 110 according to one embodiment of the present disclosure includes a plurality of dams in the non-display area NDA, and can block a flow of each of a sealant 190 and a filler 150 by using the plurality of dams.

In more detail, the transparent display panel 110 according to one embodiment of the present disclosure can further include an inner dam ID, an outer dam OD and a sealant 190, which are provided in the non-display area NDA.

The inner dam ID can include a lower inner dam LID and an upper inner dam UID. The lower inner dam LID can be provided in the non-display area NDA on the first substrate 111, and the upper inner dam UID can be provided in the non-display area NDA on the second substrate 111. The lower inner dam LID and the upper inner dam UID can be provided to overlap each other, and can be provided to face each other in the overlapped area.

The upper inner dam UID can be covered by the organic layer 180 as shown in FIG. 10. In this case, the organic layer 180 can further include a second protrusion pattern 184 protruded toward the lower inner dam in an area corresponding to the upper inner dam UID. The second protrusion pattern 184 can include a second convex surface S3 protruded from the flat surface S1 in an area overlapped with the lower inner dam LID.

The second protrusion pattern 184 provided in the area overlapped with the lower inner dam and the upper inner dam UID can block the flow of each of the filler 150 provided in the display area DA and the sealant 190 provided in the non-display area NDA. The lower inner dam LID and the second protrusion pattern 184 can block the flow of the filler 150 so that the filler 150 provided in the display area DA is not spread to an area in which the sealant 190 is formed. In addition, the lower inner dam LID and the second protrusion pattern 184 can block the flow of the sealant 190 so that the sealant 190 provided in the non-display area NDA cannot be spread to an area in which the filler 150 is formed.

The inner dam ID can be provided as a plurality of inner dams ID. The inner dam ID can include a first inner dam ID1 and a second inner dam ID2. The first inner dam ID1 and the second inner dam ID2 can be disposed to be spaced apart from each other.

In this case, the first inner dam ID1 can include a first lower inner dam LID1 and a first upper inner dam UID1. The second inner dam ID2 can include a second lower inner dam LID2 and a second upper inner dam UID2. Meanwhile, the second protrusion pattern 184 of the organic layer 180 can be provided as a plurality of second protrusion patterns 184. The second protrusion pattern 184 can include a (2-1)th protrusion pattern 184a protruded toward the first lower inner dam LID1 in an area corresponding to the first upper inner dam UID1 and a (2-2)th protrusion pattern 184b protruded toward the second lower inner dam LID2 in an area corresponding to the second upper inner dam UID2.

The (2-1)th protrusion pattern 184a provided in the area overlapped with the first lower inner dam LID1 and the first upper inner dam UID1 can block the flow of the filler 150 so that the filler 150 provided in the display area DA is not spread to the area in which the sealant 190 is formed. The first lower inner dam LID1 and the (2-1)th protrusion pattern 184a can be in contact with the filler 150 at one side.

Also, the (2-2)th protrusion pattern 184b provided in the area overlapped with the second lower inner dam LID2 and the second upper inner dam UID2 can block the flow of the sealant 190 so that the sealant 190 provided in the non-display area NDA is not spread to the area in which the filler 150 is formed. The second lower inner dam LID2 and the second-second protrusion pattern 184b can be in contact with the sealant 190 at one side.

The lower inner dam LID and the upper inner dam UID can be made of an organic material, but are not limited thereto. The lower inner dam LID can be formed of the same material on the same layer as one of the elements made of an organic material on the first substrate 111. In one embodiment, the lower inner dam LID can be formed of the same material on the same layer as the bank 125 provided on the first substrate 111.

The upper inner dam UID can be formed of the same material on the same layer as one of the elements made of an organic material on the second substrate 112. In one embodiment, the upper inner dam UID can be formed of the same material on the same layer as the black matrix BM provided on the second substrate 112.

In the transparent display panel 110 according to one embodiment of the present disclosure, the filler 150 and the sealant 190 can be spaced apart from each other with the inner dam ID interposed therebetween. Therefore, the transparent display panel 110 according to one embodiment of the present disclosure can prevent the filler 150 and the sealant 190 from being mixed with each other.

Also, in the transparent display panel 110 according to one embodiment of the present disclosure, the organic layer 180 can be formed to cover the upper inner dam UID. When the first substrate 111 and the second substrate 112 are bonded to each other, bubbles can mainly occur in a portion where the filler 150 and the inner dam ID are in contact with each other. In the transparent display panel according to one embodiment of the present disclosure, the organic layer 180 can be formed up to an area, in which the upper inner dam UID is provided, on the second substrate 112, whereby occurrence of bubbles at the edge of the filler 150 can be minimized.

Also, in the transparent display panel 110 according to one embodiment of the present disclosure, the organic layer 180 is provided between the lower inner dam LID and the upper inner dam UID and the second protrusion pattern 184 is formed in the organic layer 180, whereby the spaced distance between the first substrate 111 and the second substrate 112 in the non-display area NDA can be significantly reduced. Therefore, the transparent display panel 110 according to one embodiment of the present disclosure can more effectively block the flow of each of the filler 150 and the sealant 190.

The outer dam OD can include a lower outer dam LOD and an upper outer dam UOD. The lower outer dam LOD can be provided in the non-display area NDA on the first substrate 111, and the upper outer dam UOD can be provided in the non-display area NDA on the second substrate 111. The lower outer dam LOD and the upper outer dam UOD can be provided to overlap each other, and can be provided to face each other in the overlapped area.

The lower outer dam LOD and the upper outer dam UOD can block the flow of the sealant 190 provided in the non-display area NDA. The lower outer dam LOD and the upper outer dam UOD can prevent the sealant 190 provided in the non-display area NDA from overflowing to the outside.

The outer dam OD can be provided as a plurality of outer dams OD. The outer dam OD can include a first outer dam OD1 and a second outer dam OD2. The first outer dam OD1 and the second outer dam OD2 can be disposed to be spaced apart from each other.

In this case, the first outer dam OD1 can include a first lower outer dam LOD1 and a first upper outer dam UOD1. The second outer dam OD2 can include a second lower outer dam LOD2 and a second upper outer dam UOD2.

The first lower outer dam LOD1 and the first upper outer dam UOD1 can block the flow of the sealant 190 so that the sealant 190 provided in the non-display area NDA does not overflow to the outside. The first lower outer dam LOD1 and the first upper outer dam UOD1 can be in contact with the sealant 190 at one side.

In addition, the second lower outer dam LOD2 and the second upper outer dam UOD2 can prevent the sealant 190, which overflows from the first lower outer dam LOD1 and the first upper outer dam UOD1, from overflowing to the outside.

The lower outer dam LOD and the upper outer dam UOD can be made of an organic material, but are not limited thereto. The lower outer dam LOD can be formed of the same material on the same layer as one of the elements made of an organic material on the first substrate 111. In one embodiment, the lower outer dam LOD can be formed of the same material on the same layer as the bank 125 provided on the first substrate 111.

The upper outer dam UOD can be formed of the same material on the same layer as one of the elements made of the organic material on the second substrate 112. In one embodiment, the upper outer dam UOD can be formed of the same material on the same layer as the black matrix BM provided on the second substrate 112.

The sealant 190 can be provided between the first substrate 111 and the second substrate 112 in the non-display area NDA to bond the first substrate 111 and the second substrate 112 to each other. The filler 150 can be a thermosetting resin or a UV curable resin, and can be made of an organic material having an adhesive property. The sealant 190 can be made of a material different from that of the filler 150, but is not limited thereto.

Meanwhile, FIG. 10 shows that the upper inner dam LID is provided, but the present disclosure is not limited thereto. In another embodiment, the upper inner dam LID can be omitted as shown in FIG. 11. In this case, the second protrusion pattern 184 of the organic layer 180 can be the upper inner dam. The (2-1)th protrusion pattern 184a can be the first upper inner dam LID1 provided to face the first lower inner dam UID1, and the (2-2)th protrusion pattern 184b can be the second upper inner dam UID2 provided to face the second lower inner dam LID2.

The upper outer dam UOD can be formed of the same material on the same layer as the black matrix BM provided on the second substrate 112, but is not limited thereto. The upper outer dam UOD can be formed of the same material on the same layer as the organic layer 180.

FIGS. 10 and 11 show that the upper outer dam UOD has a thickness smaller than that of the organic layer 180, but the present disclosure is not limited thereto. In another embodiment, the upper outer dam UOD can have the same thickness as that of the organic layer 180 as shown in FIG. 12. The upper outer dam UOD can include a third protrusion pattern 186 protruded toward the lower outer dam LOD in an area corresponding to the lower outer dam LOD.

The upper outer dam UOD can include a (3-1)th protrusion pattern 186a protruded toward the first lower outer dam LOD1 in an area overlapped with the first lower outer dam LOD1 and a (3-2)th protrusion pattern 186b protruded toward the second lower outer dam in an area overlapped with the second lower outer dam LOD2. In this case, the (3-1)th protrusion pattern 186a can be the first upper outer dam UOD1 provided to face the first lower outer dam LOD2, and the (3-2)th protrusion pattern 186b can be a second upper outer dam UOD2 provided to face the second lower outer dam LOD2. The upper outer dam UOD can be formed of the same material on the same layer as the organic layer 180.

In the transparent display panel 110 according to one embodiment of the present disclosure, the thickness of the upper outer dam UOD can be increased so that the spaced distance between the first substrate 111 and the second substrate 112 in the non-display area NDA can be significantly reduced in the edge area. Therefore, the transparent display panel 110 according to one embodiment of the present disclosure can more effectively block the sealant 190 from overflowing to the outside.

According to the present disclosure, the following advantageous effects may be obtained.

In the present disclosure, the touch sensor electrode of the touch sensor and the cathode electrode of the light emitting element may be simultaneously formed using the undercut structure, whereby the touch process may be simplified and a separate mask for the touch sensor electrode is not required additionally. Therefore, the present disclosure may implement process optimization and reduce production energy.

Also, in the present disclosure, the organic layer is provided on the second substrate in which the color filter and the black matrix are provided, whereby the step difference due to the color filter and the black matrix may be planarized. Therefore, in the present disclosure, the step difference between the non-transmissive area and the transmissive area, which is generated by the color filter and the black matrix on the second substrate, may be compensated.

Also, in the present disclosure, the organic layer is provided with the protrusion pattern protruded toward the touch sensor electrode, whereby the spaced distance between the touch sensor electrode and the organic layer may be reduced. That is, in the present disclosure, the step difference between the non-transmissive area and the transmissive area, which is generated on the first substrate, may be compensated.

Also, in the present disclosure, the difference between the spaced distance between the first substrate and the second substrate in the non-transmissive area and the spaced distance between the first substrate and the second substrate in the transmissive area may be reduced, whereby the filler may be uniformly spread and filled in the non-transmissive area and the transmissive area. In the present disclosure, the area in which the filler is not filled may be prevented from being generated, whereby occurrence of the stain or deterioration of visibility may be prevented from being caused due to the filler.

Also, in the present disclosure, the organic layer may be formed up to the area, in which the upper inner dam is provided, in the non-display area, whereby occurrence of bubbles at the edge of the filler may be minimized or at least reduced.

Also, in the present disclosure, the organic layer is provided with the protrusion pattern formed between the lower inner dam and the upper inner dam, whereby the spaced distance between the first substrate and the second substrate in the non-display area may be reduced. Therefore, the present disclosure may more effectively block the flow of each of the filler and the sealant.

It will be apparent to those skilled in the art that the present disclosure described above is not limited by the above-described embodiments and the accompanying drawings and that various substitutions, modifications and variations may be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A transparent display device, the transparent display device comprising:
a first substrate comprising a display area including a transmissive area and a non-transmissive area and a non-display area near the display area;
a second substrate facing the first substrate;
a plurality of subpixels in the non-transmissive area and over the first substrate, the plurality of subpixels including a light emitting element including an anode electrode, a light emitting layer, and a cathode electrode;
a touch sensor in the transmissive area and over the first substrate, the touch sensor including a touch sensor electrode; and
an organic layer over one surface of the second substrate that faces the first substrate, the organic layer including a first protrusion pattern that protrudes toward the touch sensor in an area overlapped with the touch sensor.

2. The transparent display device of claim 1, wherein the organic layer includes a flat surface in an area overlapped with the plurality of subpixels and a convex surface in an area overlapped with the touch sensor.

3. The transparent display device of claim 1, further comprising:
a plurality of color filters that correspond to each of the plurality of subpixels over the one surface of the second substrate; and
a black matrix between the plurality of color filters,
wherein the organic layer covers the plurality of color filters and the black matrix.

4. The transparent display device of claim 1, further comprising:
an undercut structure along an edge of the transmissive area, wherein the cathode electrode included in the light emitting element and the touch sensor electrode included in the touch sensor are on a same layer and separated from each other by the undercut structure.

5. The transparent display device of claim 4, wherein the undercut structure has a closed shape on a plane in the transmissive area.

6. The transparent display device of claim 4, wherein the undercut structure includes:
a plurality of inorganic layers including a first opening area that overlaps an edge area of the touch sensor electrode and a second opening area between the non-transmissive area and the first opening area; and
an organic pattern over the plurality of inorganic layers and between the first opening area and the second opening area.

7. The transparent display device of claim 4, wherein the first protrusion pattern is in an area surrounded by the undercut structure.

8. The transparent display device of claim 1, further comprising:
a filler between the cathode electrode included in the light emitting element and the organic layer and between the touch sensor electrode included in the touch sensor and the organic layer.

9. The transparent display device of claim 8, further comprising:
a lower inner dam in the non-display area over the first substrate, the lower inner dam configured to block a flow of the filler; and
an upper inner dam in the non-display area over the second substrate and overlapping the lower inner dam.

10. The transparent display device of claim 9, wherein the organic layer covers the upper inner dam.

11. The transparent display device of claim 9, wherein the organic layer further includes a second protrusion pattern that protrudes toward the lower inner dam in an area corresponding to the upper inner dam.

12. The transparent display device of claim 11, wherein the second protrusion pattern overlaps the lower inner dam.

13. The transparent display device of claim 9, wherein each of the lower inner dam and the upper inner dam is spaced apart from the display area and surrounds the display area, and the filler is in an area surrounded by the lower inner dam and the upper inner dam.

14. The transparent display device of claim 9, further comprising:
a bank between the plurality of subpixels on the first substrate; and
a black matrix in an area overlapped with the bank on the one surface of the second substrate,
wherein the lower inner dam includes a same material and is on a same layer as the bank, and
the upper inner dam comprises a same material and is on a same layer as the black matrix.

15. The transparent display device of claim 8, further comprising:
a lower inner dam in the non-display area over the first substrate, the lower inner dam configured to block a flow of the filler,
wherein the organic layer further includes a second protrusion pattern that protrudes toward the lower inner dam in an area overlapped with the lower inner dam.

16. The transparent display device of claim 8, further comprising:
a sealant in the non-display area and bond the first substrate and the second substrate to each other, wherein the sealant is spaced apart from the filler.

17. The transparent display device of claim 16, further comprising:
a lower outer dam in an edge area of the first substrate on the first substrate, the lower outer dam configured to block a flow of the sealant; and
an upper outer dam in an edge area of the second substrate on the one surface of the second substrate, the upper outer dam configured to block the flow of the sealant.

18. The transparent display device of claim 17, wherein the upper outer dam comprises a same material as the organic layer.

19. The transparent display device of claim 17, wherein the upper outer dam has a same thickness as the organic layer.

20. The transparent display device of claim 17, wherein the upper outer dam includes a third protrusion pattern that protrudes toward the lower outer dam in an area overlapped with the lower outer dam.
